(19) United States
(12) Patent Application Publication
(10) Pub. No.: US 2024/0061033 A1
(43) Pub. Date: Feb. 22, 2024

(54) INSPECTION DEVICE AND INSPECTION METHOD USING THE SAME

(71) Applicant: Samsung Display Co., Ltd., Yongin-si (KR)

(72) Inventors: Junghun Sin, Yongin-si (KR); Sangwook Yoo, Yongin-si (KR); Junseong Lee, Yongin-si (KR); Taejoon Kim, Yongin-si (KR)

(21) Appl. No.: 18/450,155

(22) Filed: Aug. 15, 2023

(30) Foreign Application Priority Data
Aug. 16, 2022 (KR) 10-2022-0102231

(51) Int. Cl. G01R 31/28; G06F 3/041

(52) U.S. Cl. CPC G01R 31/2829; G06F 3/0416; G06F 3/0446

(57) ABSTRACT

Provided is an inspection device for inspecting a touch-sensing device including a plurality of touch sensors, the inspection device including a data receiver configured to receive raw data from a touch integrated circuit (IC) that is configured to supply a signal for inspection to the touch-sensing device, and that is configured to measure a value output from the touch-sensing device, and a data processor configured to determine operability of the touch-sensing device by using the raw data, and configured to remove noise from the raw data by using first data measured when the touch-sensing device is not electrically connected to the touch IC.

### CROSS-REFERENCE TO RELATED APPLICATION

This application claims priority to, and the benefit of, Korean Patent Application No. 10-2022-0102231, filed on Aug. 16, 2022, in the Korean Intellectual Property Office, the disclosure of which is incorporated by reference herein in its entirety.

### BACKGROUND

### 1. Field

One or more embodiments relate to touch unit inspection devices and inspection methods using the same.

### 2. Description of the Related Art

A touch panel is an input device that allows an input of a user's command to select instruction content displayed on a screen of an image display device and the like by using a user's finger or an object. To this end, a touch panel is provided on an image display device, and converts a touch position directly contacted by a user's finger or an object into an electrical signal. Accordingly, instruction content selected at the touch position is accepted as an input signal. As the touch panel may replace a separate input device, such as a keyboard or a mouse, which operates in connection with an image display device, the scope of a use thereof is gradually expanding.

A resistive film method, a light-sensing method, a capacitance method, and the like have been known as a method of implementing a touch panel. Among them, a touch panel employing the capacitance method may determine a touch position by detecting a change in capacitance that occurs when a user's finger or an object is in contact therewith.

The touch panel employing the capacitance method passes through an inspection process to detect defects before shipment.

### SUMMARY

One or more embodiments include inspection devices which may determine whether a touch-sensing device normally operates based on touch sensor data from which noise by an inspection system is removed. However, such an aspect is only an example, and the scope of the present disclosure is not limited thereby.

Additional aspects will be set forth in part in the description which follows and, in part, will be apparent from the description, or may be learned by practice of the presented embodiments of the disclosure.

According to one or more embodiments, an inspection device is for inspecting a touch unit including a plurality of touch sensors, the inspection device includes a data receiver configured to receive raw data from a touch integrated circuit (IC) that is configured to supply a signal for inspection to the touch-sensing device, and that is configured to measure a value output from the touch-sensing device, and a data processor configured to determine operability of the touch-sensing device by using the raw data, and configured to remove noise from the raw data by using first data measured when the touch-sensing device is not electrically connected to the touch IC.

The raw data may include second data measured when the touch-sensing device is electrically connected to the touch IC.

The data processor may be further configured to obtain touch sensor data by removing noise from the second data, and determine the operability of the touch-sensing device based on the touch sensor data.

The first data may include a first capacitance value with respect to a jig wiring and the touch IC, the jig wiring electrically connecting the touch-sensing device to the touch IC, wherein the second data includes a second capacitance value with respect to the touch IC, the jig wiring, and the touch-sensing device.

The data processor may be further configured to remove noise by using a touch IC intrinsic coefficient having different values for respective types of the touch IC.

The touch IC intrinsic coefficient may be determined by comparing data for respective inspection systems, and by calculating an average noise change rate.

The touch IC intrinsic coefficient may be extracted based on a lookup table containing data for respective inspection systems.

The touch IC intrinsic coefficient and the first data may be stored in a memory.

The touch sensor data may have a value obtained by subtracting, from the second data, a value obtained by multiplying the first data by the touch IC intrinsic coefficient.

The touch sensor data may have a constant value for different inspection systems.

According to one or more embodiments, a method of inspecting a touch-sensing device including a plurality of touch sensors, includes calculating first data when a touch integrated circuit (IC) is not electrically connected to the touch-sensing device, the touch IC being configured to supply a signal for inspection to the touch-sensing device, and configured to measure a value output from the touch-sensing device, receiving raw data from the touch IC, removing noise from the raw data, by using the first data, and determining operability of the touch-sensing device based on the raw data from which noise is removed.

The receiving of the raw data may include calculating second data when the touch-sensing device is electrically connected to the touch IC.

The removing of the noise may include obtaining touch sensor data by removing noise in the second data, wherein the determining the operability of the touch-sensing device is based on the touch sensor data.

The first data may include a first capacitance value with respect to a jig wiring and the touch IC, the jig wiring being for electrically connecting the touch-sensing device to the touch IC, wherein the second data includes a second capacitance value with respect to the touch IC, the jig wiring, and the touch-sensing device.

The method may further include obtaining a touch IC intrinsic coefficient having different values for respective types of the touch IC, wherein the removing of the noise includes using the touch IC intrinsic coefficient.

The obtaining of the touch IC intrinsic coefficient may include comparing data for different inspection systems, and calculating an average noise change rate.

The obtaining of the touch IC intrinsic coefficient may be based on a lookup table (LUT) containing data for different inspection systems.

The method may further include storing the touch IC intrinsic coefficient and the first data in a memory.

The obtaining of the touch sensor data may include calculating a value obtained by subtracting, from the second data, a value obtained by multiplying the first data by the touch IC intrinsic coefficient.

### BRIEF DESCRIPTION OF THE DRAWINGS

The above and other aspects of embodiments of the disclosure will be more apparent from the following description taken in conjunction with the accompanying drawings, in which:

FIG. 1 is a schematic exploded perspective view of a display device that is a subject to be inspected by an inspection device, according to one or more embodiments;

FIG. 2 is a schematic plan view of a touch unit of the display device of FIG. 1;

FIG. 3 is a block diagram of an inspection system including an inspection device, according to one or more embodiments;

FIG. 4 is a flowchart of an inspection method using an inspection device, according to one or more embodiments;

FIGS. 5A, 5B, and 5C are schematic plan views of various inspection systems;

FIG. 6 is a graph showing data measured by an inspection method using an inspection device, according to the related art;

FIGS. 7A and 7B are schematic plan views of an inspection system including an inspection device, according to one or more embodiments; and

FIGS. 8A to 8C are graphs showing data measured by an inspection method using an inspection device, according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

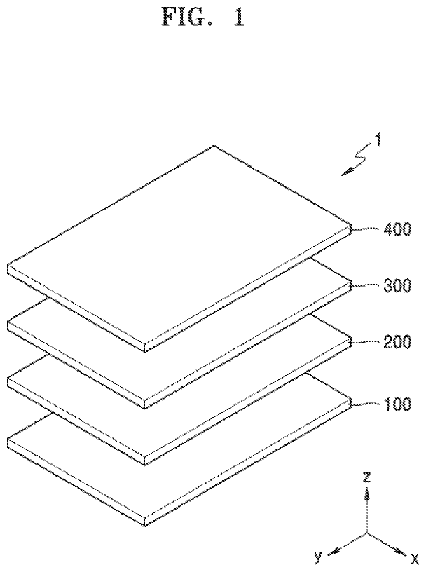

FIG. 1 is a schematic exploded perspective view of a display device 1 that is a subject to be inspected by an inspection device, according to one or more embodiments.

Referring to FIG. 1, the display device 1 may include a display panel 100, a touch unit (e.g., touch-sensing device) 200 located above the display panel 100, a polarization unit (e.g., polarizer) 300 located above the touch-sensing device 200, and a cover window 400 located above the polarizer 300. As one or more embodiments, respective adhesive layers may be further provided between the display panel 100 and the touch-sensing device 200, between the touch-sensing device 200 and the polarizer 300, and between the polarizer 300 and the cover window 400. Furthermore, in one or more other embodiments, the polarizer 300 may be provided between the display panel 100 and the touch-sensing device 200.

The touch-sensing device 200 that is a subject to be inspected by an inspection device according to one or more embodiments may be attached to the display panel 100 as a separate panel by using an adhesive, or may be integrally provided with the display panel 100 in the display panel 100.

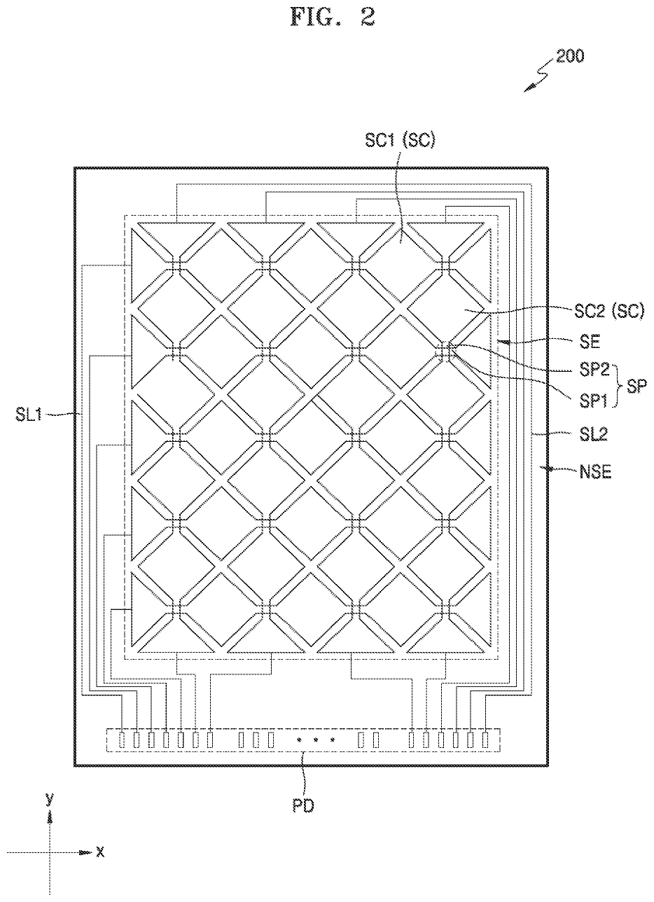

FIG. 2 is a schematic plan view of the touch-sensing device 200 of the display device 1 of FIG. 1.

Referring to FIG. 2, the touch-sensing device 200 is operated by forming an electrical signal according to a user's touch. FIG. 2 illustrates the touch-sensing device 200 of an electrostatic capacitive type, but this is an example. In one or more embodiments, the touch-sensing device 200 may be any one selected from among a resistive type, an electro-magnetic type, a surface acoustic wave type (saw type), and/or an infrared type.

Referring to FIG. 2, the touch-sensing device 200 may include a plurality of touch electrodes SC respectively including a plurality of touch sensors. The touch electrodes SC may be electrically connected to each other via connection patterns SP. The touch-sensing device 200 may further include, in an outer area of the touch electrodes SC, first and second signal wirings SL1 and SL2 that connect the touch electrodes SC to an external driving circuit via a pad portion PD, in one or more embodiments.

As one or more embodiments, when the touch-sensing device 200 is provided as a separate panel, the touch electrodes SC and the connection patterns SP may be formed on a separate transparent substrate. In one or more other embodiments, when the touch-sensing device 200 is not provided as a separate panel, but instead is formed directly on the display panel 100, the touch electrodes SC and the connection patterns SP may be formed above an encapsulation portion, in one or more embodiments.

The touch electrodes SC may include first sensor portions SC1 connected to each other in a first direction (X-axis direction), and second sensor portions SC2 arranged to be respectively distributed between the first sensor portions SC1 and not to overlap the first sensor portions SC1, and to be connected to each other in a second direction (Y-axis direction) that is substantially perpendicular to the first direction (X-axis direction). The first sensor portions SC1 and the second sensor portions SC2 are arranged to be alternately distributed in a touch active area SE not to overlap each other.

The first direction (X-axis direction) in which the first sensor portions SC1 are connected to each other, and the second direction (Y-axis direction) in which the second sensor portions SC2 are connected to each other, are different directions crossing each other, and for example, when the first direction (X-axis direction) is set in a row direction, the second direction (Y-axis direction) is set in a column direction.

In other words, while the first sensor portions SC1 are arranged in multiples respectively in a column line and/or a row line, the first sensor portions SC1 arranged in the same column line or row line (in the present example, the same row line) are connected to each other in the first direction (X-axis direction) by a plurality of first connection patterns SP1 arranged in the same column line or row line. In this state, the first sensor portions SC1 are respectively connected to the first signal wiring SL1 in units of lines connected in the first direction (X-axis direction).

While the second sensor portions SC2 are arranged in multiples respectively in each of a row line and/or a column line, the second sensor portions SC2 arranged in the same row line or column line (in the present example, the same column line) are connected to each other in the second direction (Y-axis direction) crossing the first direction by a plurality of second connection patterns SP2 arranged in the same row line or column line. In this state, the second sensor portions SC2 are respectively connected to the second signal wiring SL2 in units of lines connected in the second direction (Y-axis direction).

The first and second sensor portions SC1 and SC2 may each be implemented to be transparent to have a certain transmittance or more, such that light from the display panel 100 arranged below may be transmitted therethrough. For example, the first and second sensor portions SC1 and SC2 may each include a transparent electrode layer formed of a transparent electrode material, such as at least an indium tin oxide (ITO).

The connection patterns SP may include the first connection patterns SP1 formed in the first direction (X-axis direction) to connect the first sensor portions SC1 to each other in the first direction (X-axis direction), and the second connection patterns SP2 formed in the second direction (Y-axis direction) to connect the second sensor portions SC2 to each other in the second direction (Y-axis direction). The connection patterns SP are formed of a transparent electrode material or an opaque low-resistance electrode material, and the thickness, width, or the like thereof may be adjusted to prevent visualization/visual recognition thereof.

The first and second signal wirings SL1 and SL2 are respectively electrically connected to the first sensor portions SC1 and the second sensor portions SC2 in units of lines connected in the first direction (X-axis direction) and the second direction (Y-axis direction), and connect the first sensor portions SC1 and the second sensor portions SC2 to the external driving circuit, such as a touch detection circuit, via the pad portion PD. The first and second signal wirings SL1 and SL2 as above are arranged in a touch inactive area NSE defined outside the touch active area SE to avoid the touch active area SE where an image is displayed. As a material selection range is wide, the first and second signal wirings SL1 and SL2 may be formed of a low-resistance material, such as molybdenum (Mo), silver (Ag), titanium (Ti), copper (Cu), aluminum (Al), molybdenum/aluminum/molybdenum (Mo/Al/Mo), and the like, in addition to the transparent electrode material used for the formation of the first and second sensor portions SC1 and SC2.

Although FIG. 2 illustrates one or more embodiments in which the first and second connection patterns SP1 and SP2 cross each other, the disclosure is not limited thereto. For example, the first connection patterns SP1 may connect the first sensor portions SC1 to each other in the first direction by bypassing in a path overlapping the adjacent second sensor portions SC2 without crossing the second connection patterns SP2. In this case, an insulating film for securing stability may be provided between the first connection patterns SP1 and the second sensor portions SC2.

The touch-sensing device 200 configured as above may detect a touch position by measuring a varying capacitance between the first sensor portions SC1 and the second sensor portions SC2 when an input device, such as a finger, approaches or contacts the touch-sensing device 200. In the following description, an inspection device for determining whether the touch-sensing device 200 normally operates, and an inspection system including the same, are described.

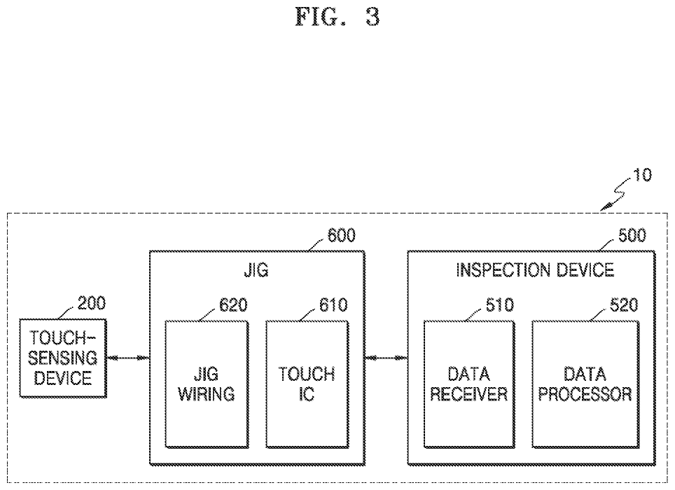

FIG. 3 is a block diagram of an inspection system 10 including an inspection device 500, according to one or more embodiments.

Referring to FIG. 3, the inspection system 10 for a touch-sensing device may include an inspection device 500 and a jig 600 for inspecting the touch-sensing device 200.

The touch-sensing device 200, as a subject to be inspected by the inspection system 10, is fastened to the jig 600, and may be electrically connected to the inspection device 500 and to a touch integrated circuit (IC) 610 placed on the jig 600.

The jig 600 may be connected between the inspection device 500 and the touch-sensing device 200, and may support the touch IC 610 and a jig wiring 620. The jig 600 may be integrally formed with the inspection device 500.

The touch IC 610 may be placed on the jig 600, and may inspect the performance of a touch sensor. The touch IC 610 may be referred to as a touch inspection circuit and may be implemented as a single IC. The touch IC 610 may include a drive unit (e.g., driver), a detection unit (e.g., detector), and an inspection unit (e.g. inspector), in one or more embodiments.

The driver of the touch IC 610 may drive the touch-sensing device 200. The driver of the touch IC 610 may generate touch drive signals to inspect the touch-sensing device 200, and may supply the generated touch drive signals to the touch electrodes SC formed in the touch-sensing device 200. When the touch drive signals are supplied thereto, a capacitance formed in a touch electrode is changed by an external touch.

The detector may detect a charge change amount of mutual capacitance of touch nodes corresponding to intersections of the first sensor portions SC1 and the second sensor portions SC2. The detector may include an operation amplifier for detecting a charge change amount of mutual capacitance of touch nodes.

The inspector may determine whether a corresponding touch electrode is defective by comparing a detected capacitance value with a reference range. In other words, the inspector may inspect whether a capacitance value is in a reference range. For example, the inspector may determine a corresponding touch sensor to be defective when a capacitance value is not in a reference range. However, the capacitance value determined by the inspector may be a value that is corrected by a data processing unit (e.g., data processor) 520 of the inspection device 500.

The jig wiring 620 for connecting the inspection device 500, the touch IC 610, and the touch-sensing device 200 to one another may be arranged on the jig 600. The jig wiring 620 may be configured to transmit power, a signal(s), and the like between the inspection device 500, the touch IC 610, and the touch-sensing device 200.

The inspection device 500 may receive and process data that is transmitted from a subject to be inspected, such as the touch-sensing device 200, to the touch IC 610. The inspection system 10 may determine whether the touch-sensing device 200 normally operates based on the data corrected in the inspection device 500.

A data receiving unit (e.g., data receiver) 510 may receive raw data from the touch IC 610. The data receiver 510 may receive, through the touch IC 610, a capacitance value output from the touch-sensing device 200 as feedback of the touch drive signals supplied to the touch-sensing device 200.

The data processor 520 may perform digital processing on the received raw data as evaluation data for inspection of the touch-sensing device 200. The data processor 520 may convert the received capacitance value into digital data, and may remove noise therefrom. In other words, the data processor 520 may calculate touch sensor data that is data corrected for inspection based on the received raw data.

In detail, the data processor 520 may include a memory and a data correction unit (e.g., data corrector). Initial characteristics data for each inspection system may be stored in the memory. The initial characteristics data for each inspection system may include an intrinsic coefficient for each touch IC and first data, which are described below. The initial characteristics data for each inspection system may be collected in a test process after manufacturing the inspection system 10.

The data corrector may correct raw data by using the initial characteristics data for each inspection system. The raw data may each include touch sensor data and a noise component. Accordingly, the data corrector performs correction of removing a noise component from the raw data, thereby securing touch sensor data.

In other words, the data processor 520 may calculate touch sensor data by comparing and using the initial characteristics data for each inspection system stored in the memory with the raw data received from the data receiver 510.

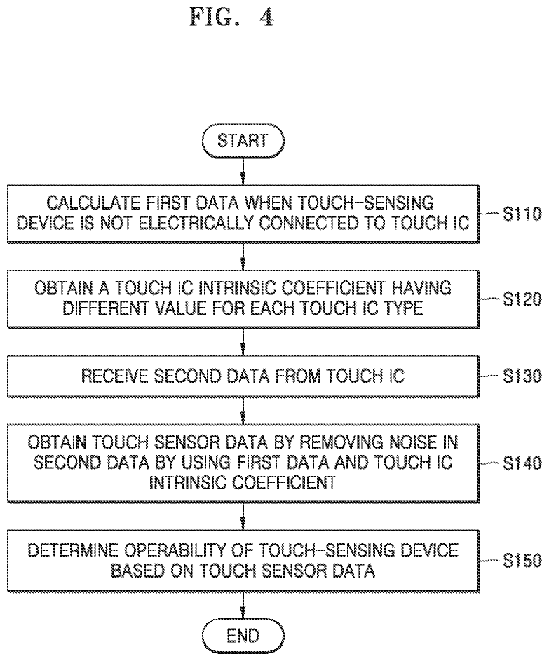

FIG. 4 is a flowchart of an inspection method by using an inspection device, according to one or more embodiments.

Referring to FIG. 4, a touch-sensing device inspection method may include calculating first data when a touch-sensing device is not electrically connected to a touch IC (S110), obtaining a touch IC intrinsic coefficient having a different value for each touch IC type (S120), receiving second data from the touch IC (S130), obtaining touch sensor data by removing noise in the second data by using the first data and the touch IC intrinsic coefficient (S140), and determining operation of the touch-sensing device based on the touch sensor data (S150).

First, first data, which is measured when the touch-sensing device 200 is not electrically connected to the touch IC 610, may be calculated in each inspection system 10 (S110). In other words, the first data is a value of data obtained by performing an inspection when the touch-sensing device 200 is not fastened to the inspection system 10. Accordingly, the first data may include a capacitance value with respect to the touch IC 610 and the jig wiring 620. The first data may be stored, as initial characteristics data for each inspection system 10, in the memory of the data processor 520.

Next, a touch IC intrinsic coefficient having a different value may be obtained from each inspection system 10 (S120). The touch IC intrinsic coefficient may have a different value for each type of the touch IC 610. The touch IC intrinsic coefficient may be determined by calculating an average noise change rate by comparing data for each inspection system 10. In detail, the touch IC intrinsic coefficient may be determined as a ratio of noise data of the inspection system 10 to the average noise data by performing an inspection on the same sample for each inspection system 10.

The touch IC intrinsic coefficient may be stored, as initial characteristics data for each inspection system 10, and like the first data, in the memory of the data processor 520. As an example, the memory may include a lookup table (LUT), and the touch IC intrinsic coefficient may be extracted based on an LUT containing data for each inspection system 10.

Next, second data measured when the touch-sensing device 200 is electrically connected to the touch IC 610 may be received (S130). To determine the normal operation of the touch-sensing device 200, raw data, that is, second data, may be secured when the touch-sensing device 200 is fastened to the inspection system 10. Accordingly, the second data may include a capacitance value with respect to the touch IC 610, the jig wiring 620, and the touch-sensing device 200. The data receiver 510 may receive the second data from the touch IC 610.

Next, touch sensor data may be obtained by removing noise in the second data by using the first data and the touch IC intrinsic coefficient (S140). When removing noise in the raw data, the data processor 520 may remove noise by using the first data and the touch IC intrinsic coefficient. As the raw data includes not only a capacitance value with respect to a touch sensor, but also a noise component, touch sensor data having an intrinsic capacitance value of the touch-sensing device 200 may be obtained by removing noise.

In detail, noise data to be removed from the raw data to calculate the touch sensor data may be generated by multiplying the first data by the touch IC intrinsic coefficient. In other words, the touch sensor data may have a value obtained by subtracting, from the second data, a value obtained by multiplying the first data by the touch IC intrinsic coefficient. The touch sensor data may be represented by Equation 1 below.

Tdata=DATA2−(α×DATA1) Equation 1

In Equation 1, “Tdata” denotes touch sensor data, “DATA2” denotes second data, “α” denotes a touch IC intrinsic coefficient, and “DATA1” denotes first data. In other words, the first data has a capacitance value with respect to the touch IC 610 and the jig wiring 620, and by multiplying the first data by the touch IC intrinsic coefficient, noise data by the touch IC 610 and the jig wiring 620 in each inspection system 10 may be obtained. The second data has a capacitance value with respect to the touch IC 610, the jig wiring 620, and the touch-sensing device 200, and by removing the noise data described above from the second data, each piece of intrinsic touch sensor data of the touch-sensing device 200 may be obtained.

As a result, the touch sensor data may have a constant value even when calculated in a different inspection system 10. In other words, the touch sensor data of a corresponding touch-sensing device 200 may have the same value even when measured in different inspection systems 10.

Finally, whether the touch-sensing device 200 normally operates may be determined based on the touch sensor data (S150). The touch sensor data is a value obtained by removing noise from the raw data, and when the operation of a touch-sensing device is determined based on the touch sensor data, as the operation may be determined based on an intrinsic capacitance value of the touch-sensing device 200, more accurate inspection may be performed.

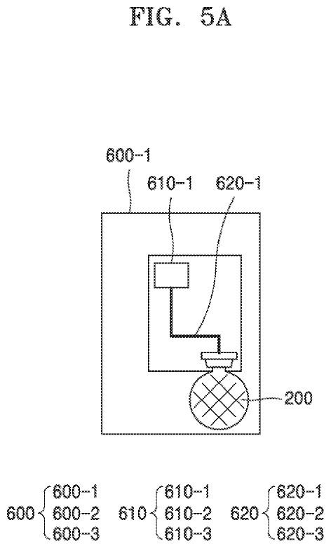

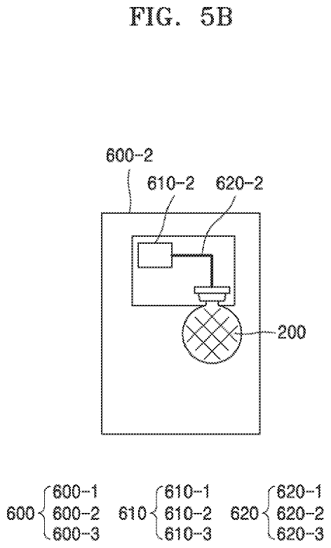

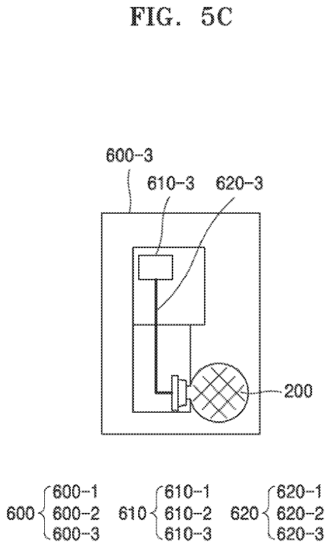

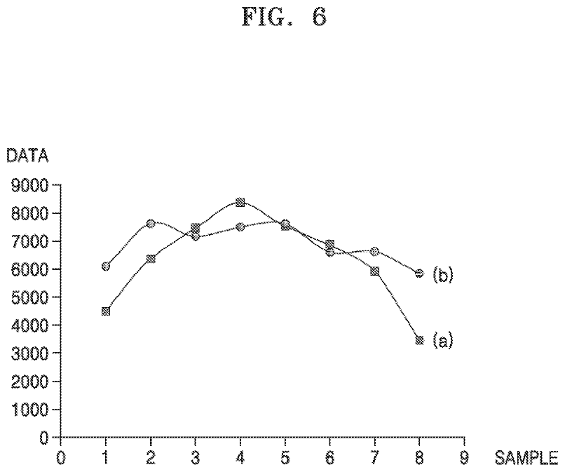

FIGS. 5A, 5B, and 5C are schematic plan view of various inspection systems, and FIG. 6 is a graph showing data measured by an inspection method using an inspection device, according to the related art.

Referring to FIGS. 5A, 5B, and 5C, inspection systems have different structures. The same touch-sensing device 200 is fastened to all of a jig 600-1 of the inspection system of FIG. 5A, a jig 600-2 of the inspection system of FIG. 5B, and a jig 600-3 of the inspection system of FIG. 5C. However, a touch IC 610-1 of the inspection system of FIG. 5A, a touch IC 610-2 of the inspection system of FIG. 5B, and a touch IC 610-3 of the inspection system of FIG. 5C may be of different types. Each of the touch ICs 610 may be products having different manufacturers or specifications. Furthermore, a jig wiring 620-1 of the inspection system of FIG. 5A, a jig wiring 620-2 of the inspection system of FIG. 5B, and a jig wiring 620-3 of the inspection system of FIG. 5C may have different respective lengths, and may be made of different respective materials.

FIG. 6 is a graph showing a comparison between raw data (a) measured by the inspection system of FIG. 5A and raw data (b) measured by the inspection system of FIG. 5B. In the experiments, sample 1 to sample 8 of the touch-sensing device 200 are measured in each of the inspection system of FIG. 5A and the inspection system of FIG. 5B, and are compared with one another. While, as in sample 5, similar values may be measured in the inspection system of FIG. 5A and the inspection system of FIG. 5B, in most other samples, the respective values measured in the inspection system of FIG. 5A and the inspection system of FIG. 5B are different from each other. For example, in the case of sample 8 of the touch-sensing device 200, a data value measured in the inspection system of FIG. 5B is about 30% higher than a data value measured in the inspection system of FIG. 5A.

As such, even when the same touch-sensing device 200 is fastened, an inspection environment varies depending on each inspection system, and thus, a capacitance value with respect to the touch-sensing device 200 being measured may be completely changed. In detail, when the touch-sensing device 200 is connected to the jig 600 and the inspection device 500, there will be inevitable resistance according to the touch IC 610 and the jig wiring 620 of the jig 600. The resistance according to the touch IC 610 and the jig wiring 620 may be negligibly small, but when the resistance has a meaningful value, the resistance may act as external noise by an inspection environment in the inspection system 10. In other words, the noise data may vary depending on the type of the touch IC 610, or the material and length of the jig wiring 620 and the like.

In other words, there has been a problem that the accuracy of inspection may be lowered because a deviation in the data value measured for each inspection system 10 is great. There is a risk that, as a result of inspection, and due to external noise by an inspection environment, a normal product may be incorrectly determined to be defective, or a defective product may be incorrectly determined to be normal.

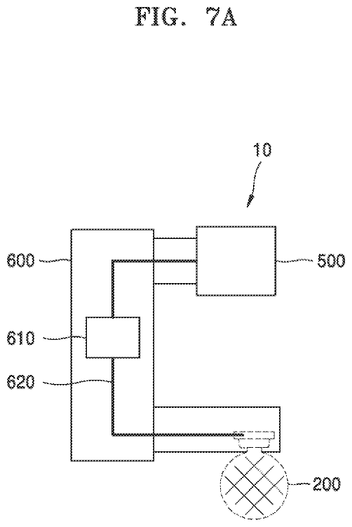

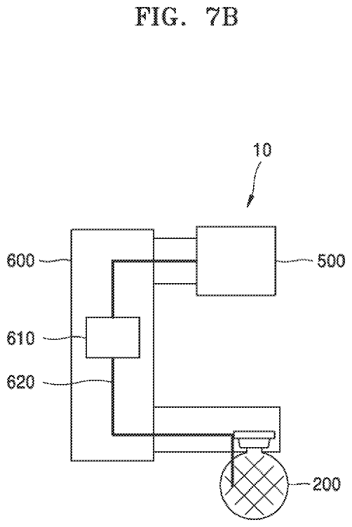

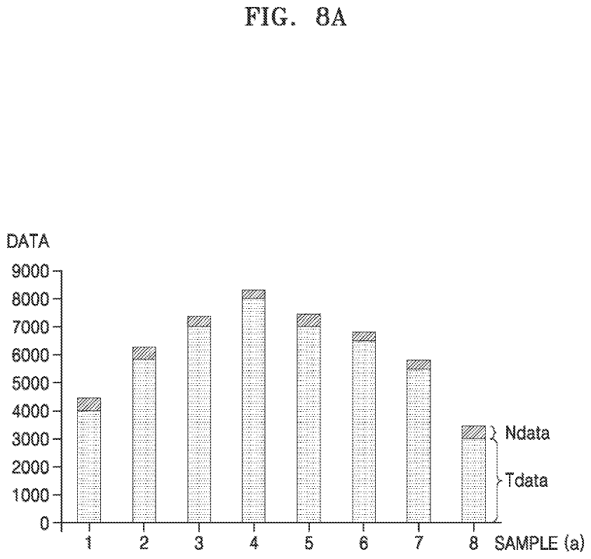

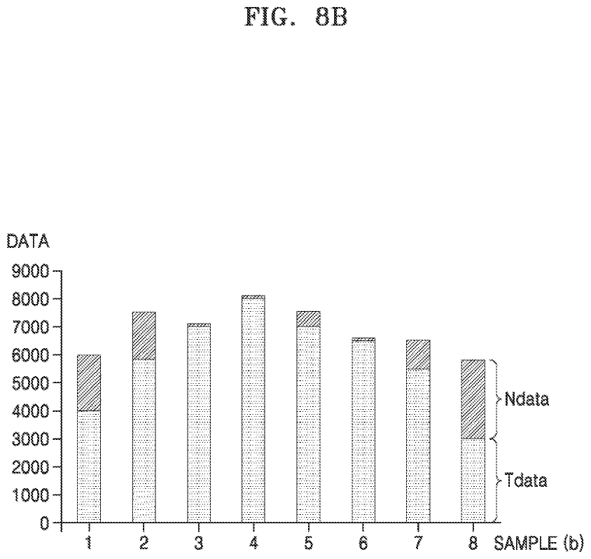

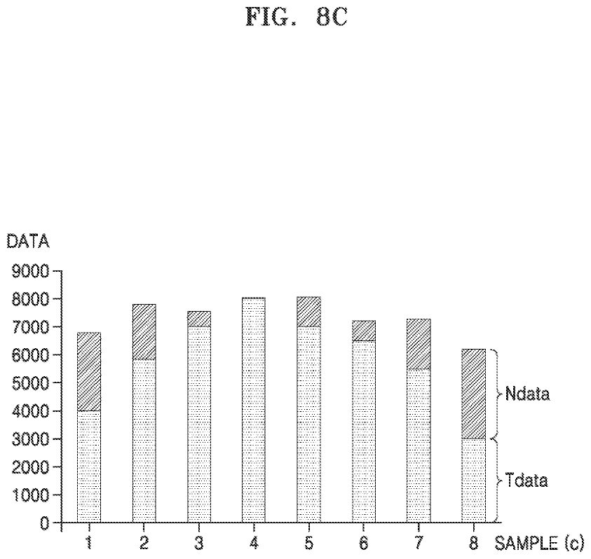

FIGS. 7A and 7B are schematic plan views of the inspection system 10 including the inspection device 500, according to one or more embodiments, and FIGS. 8A to 8C are graphs showing data measured by an inspection method using an inspection device, according to one or more embodiments.

Referring to FIGS. 7A and 7B, the inspection system 10 may include the touch-sensing device 200, the inspection device 500, the jig 600, the touch IC 610, and the jig wiring 620. In this state, as described above, the inspection device 500 may include the data receiver 510 and the data processor 520. The data receiver 510 receives raw data, and the data processor 520 removes noise from the raw data by using initial characteristics data for each inspection system, thereby obtaining touch sensor data. The initial characteristics data for each inspection system may include a touch IC intrinsic coefficient and first data.

First of all, as illustrated in FIG. 7A, first data may be measured when the touch-sensing device 200 is not fastened to the inspection device 500 and the jig 600, that is, the touch-sensing device 200 is not electrically connected to the touch IC 610. As the touch-sensing device 200 is not connected to the inspection device 500 and the jig 600, first data includes a capacitance value with respect to the touch IC 610 and the jig wiring 620 only. However, when the touch IC 610 of a different type is arranged in each inspection system 10, a touch IC intrinsic coefficient becomes different, and thus, noise data of the inspection system 10 may be calculated by multiplying first data by the touch IC intrinsic coefficient noise data of the inspection system 10.

Next, as illustrated in FIG. 7B, when the touch-sensing device 200 is fastened to the inspection device 500 and the jig 600, raw data, that is, second data, may be measured. However, the second data includes not only a capacitance value with respect to the touch-sensing device 200, but also a value including noise data of an inspection environment. In other words, as the second data includes a capacitance value with respect to the touch-sensing device 200, the touch IC 610, and the jig wiring 620 together, touch sensor data may be secured by subtracting a value with respect to the touch IC 610 and the jig wiring 620 from the second data. Accordingly, touch sensor data may be obtained by subtracting, from the second data, a value obtained by multiplying the first data by the touch IC intrinsic coefficient.

Graphs of FIGS. 8A to 8C are based on a result obtained by an inspection method using the inspection device 500 described above. The inspection environments in FIGS. 8A to 8C have different inspection systems 10 like the inspection systems of FIGS. 5A, 5B, and 5C. In other words, the inspection environments of FIGS. 8A to 8C may include the different touch IC 610 and the jig wiring 620. The graphs of FIGS. 8A to 8C are raw data results obtained by measuring the sample 1 to sample 8 of the touch-sensing device 200 in different inspection environments. The inspection result of FIGS. 8A to 8C is described with reference to Table 1 below.

TABLE 1

| | Inspection | | | | | | | | |
|---|---|---|---|---|---|---|---|---|---|
| | Inspection System | | | Inspection System | | | Inspection System | | |
| | of FIG. 5A | | | of FIG. 5B | | | of FIG. 5C | | |
| DATA | Rdata | Ndata | Tdata | Rdata | Ndata | Tdata | Rdata | Ndata | Tdata |
| S1 | 4468 | 456 | 4012 | 6023 | 2011 | 4012 | 6819 | 2807 | 4012 |
| S2 | 6291 | 489 | 5802 | 7556 | 1754 | 5802 | 7849 | 2047 | 5802 |
| S3 | 7397 | 417 | 6980 | 7128 | 148 | 6980 | 7574 | 594 | 6980 |
| S4 | 8326 | 244 | 8082 | 8437 | 355 | 8082 | 8100 | 18 | 8082 |
| S5 | 7480 | 478 | 7002 | 7556 | 554 | 7002 | 8100 | 1098 | 7002 |
| S6 | 6820 | 362 | 6458 | 6571 | 113 | 6458 | 7248 | 790 | 6458 |
| S7 | 5854 | 242 | 5612 | 6568 | 956 | 5612 | 7290 | 1678 | 5612 |
| S8 | 3428 | 378 | 3050 | 5830 | 2780 | 3050 | 6200 | 3150 | 3050 |

In Table 1, “Rdata” denotes raw data, that is, second data, “Ndata” denotes noise data, that is, a value obtained by multiplying first data by a touch IC intrinsic coefficient, and “Tdata” denotes touch sensor data.

Referring to Table 1, the inspection system of FIG. 5A, the inspection system of FIG. 5B, and the inspection system of FIG. 5C respectively have different raw data values through having the same sample. When the raw data as above is used as it is in inspection, there may be a risk of inaccurate determination of a normal operation.

In contrast, considering the touch sensor data values obtained by removing noise data through an inspection method using an inspection device, according to one or more embodiments, it may be confirmed that the same touch sensor data value is calculated in all of the inspection systems of FIGS. 5A, 5B, and 5C.

In other words, when data correction is performed in the data processor 520 included in the inspection device 500 according to the present example, the inspection of the inspection system 10 may be performed with more accurate data. As a result, the inspection device 500 according to one or more embodiments is able to address a portion in which touch sensor data is distorted by removing external noise from raw data. Furthermore, by removing noise for each inspection condition, the characteristics of a product may be accurately monitored so that quality competitiveness may be secured.

The display device according to one or more embodiments configured as above is configured to address a portion in which touch sensor data is distorted by removing external noise by the inspection system from raw data measured by the inspection device. In other words, by removing noise for each inspection condition, the characteristics of a product may be accurately monitored so that quality competitiveness may be secured. The aspects described above are merely examples, the scope of the disclosure is not limited by the above aspects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. An inspection device for inspecting a touch-sensing device comprising a plurality of touch sensors, the inspection device comprising:
a data receiver configured to receive raw data from a touch integrated circuit (IC) that is configured to supply a signal for inspection to the touch-sensing device, and that is configured to measure a value output from the touch-sensing device; and
a data processor configured to determine operability of the touch-sensing device by using the raw data, and configured to remove noise from the raw data by using first data measured when the touch-sensing device is not electrically connected to the touch IC.

2. The inspection device of claim 1, wherein the raw data comprises second data measured when the touch-sensing device is electrically connected to the touch IC.

3. The inspection device of claim 2, wherein the data processor is further configured to:
obtain touch sensor data by removing noise from the second data; and
determine the operability of the touch-sensing device based on the touch sensor data.

4. The inspection device of claim 3, wherein the first data comprises a first capacitance value with respect to a jig wiring and the touch IC, the jig wiring electrically connecting the touch-sensing device to the touch IC, and
wherein the second data comprises a second capacitance value with respect to the touch IC, the jig wiring, and the touch-sensing device.

5. The inspection device of claim 3, wherein the data processor is further configured to remove noise by using a touch IC intrinsic coefficient having different values for respective types of the touch IC.

6. The inspection device of claim 5, wherein the touch IC intrinsic coefficient is determined by comparing data for respective inspection systems, and by calculating an average noise change rate.

7. The inspection device of claim 5, wherein the touch IC intrinsic coefficient is extracted based on a lookup table containing data for respective inspection systems.

8. The inspection device of claim 5, wherein the touch IC intrinsic coefficient and the first data are stored in a memory.

9. The inspection device of claim 5, wherein the touch sensor data has a value obtained by subtracting, from the second data, a value obtained by multiplying the first data by the touch IC intrinsic coefficient.

10. The inspection device of claim 9, wherein the touch sensor data has a constant value for different inspection systems.

11. A method of inspecting a touch-sensing device including a plurality of touch sensors, the method comprising:
calculating first data when a touch integrated circuit (IC) is not electrically connected to the touch-sensing device, the touch IC being configured to supply a signal for inspection to the touch-sensing device, and configured to measure a value output from the touch-sensing device;
receiving raw data from the touch IC;
removing noise from the raw data, by using the first data; and
determining operability of the touch-sensing device based on the raw data from which noise is removed.

12. The method of claim 11, wherein the receiving of the raw data comprises calculating second data when the touch-sensing device is electrically connected to the touch IC.

13. The method of claim 12, wherein the removing of the noise comprises obtaining touch sensor data by removing noise in the second data, and
wherein the determining the operability of the touch-sensing device is based on the touch sensor data.

14. The method of claim 13, wherein the first data comprises a first capacitance value with respect to a jig wiring and the touch IC, the jig wiring being for electrically connecting the touch-sensing device to the touch IC, and
wherein the second data comprises a second capacitance value with respect to the touch IC, the jig wiring, and the touch-sensing device.

15. The method of claim 13, further comprising obtaining a touch IC intrinsic coefficient having different values for respective types of the touch IC,
wherein the removing of the noise comprises using the touch IC intrinsic coefficient.

16. The method of claim 15, wherein the obtaining of the touch IC intrinsic coefficient comprises comparing data for different inspection systems, and calculating an average noise change rate.

17. The method of claim 15, wherein the obtaining of the touch IC intrinsic coefficient is based on a lookup table (LUT) containing data for different inspection systems.

18. The method of claim 15, further comprising storing the touch IC intrinsic coefficient and the first data in a memory.

19. The method of claim 15, wherein the obtaining of the touch sensor data comprises calculating a value obtained by subtracting, from the second data, a value obtained by multiplying the first data by the touch IC intrinsic coefficient.
